(19) United States
(12) Patent Application Publication
(10) Pub. No.: US 2009/0143002 A1
(43) Pub. Date: Jun. 4, 2009

(54) COMPUTER SYSTEM AIRFLOW OPTIMIZATION AND CONFIGURATION DEVICE

(75) Inventors: Brett C. Ong, San Jose, CA (US); Barry Marshall, Santa Clara, CA (US); William A. De Meulenaere, Newark, CA (US)

Correspondence Address: OSHA LIANG L.L.P./SUN, TWO HOUSTON CENTER, 909 FANNIN, SUITE 3500, HOUSTON, TX, 77010, US

(73) Assignee: Sun Microsystem, Inc., Santa Clara, CA (US)

(21) Appl. No.: 11/948,482

(22) Filed: Nov. 30, 2007

(51) Int. Cl. H05K 5/00

(52) U.S. Cl. 454/184

(57) ABSTRACT

The air flow optimization apparatus includes a first member configured to attach to openings of an air vent on a server enclosure, such that the attachment of the first member to the air vent prevents air leakage. Further, the air flow optimization apparatus includes a second member configured to mount on top of a fan module connector within the server enclosure. A method for installing the air flow optimization apparatus includes inserting the first member into the openings of the air vent in a server enclosure, such that the first member includes attaching fins configured to be inserted into outer ends of the openings of the air vent. Further, the method for installing the air flow optimization apparatus also includes mounting the second member on top of a fan module connector, such that the second member includes engaging portions configured to engage with the fan module connector.

### BACKGROUND OF INVENTION

### Field of the Invention

As generally referred to in the art, a “server” is a computing device that is configured to perform operations for one or more other computing devices connected over a network. For an entity that requires computing infrastructure for handling relatively large amounts of network data, it is desirable to use servers that are designed to promote organizational/space efficiency and operational performance. In this regard, some servers are designed to be arranged in a “rack,” whereby the rack (or “cabinet”) houses numerous servers that are arranged, or “mounted,” vertically one on top of another (however, not necessarily in contact with one another). Such a server is generally referred to in the art as a “rackmount” server.

Specifically, one of ordinary skill in the art will appreciate that rackmount servers are generally designed having a height corresponding to whole multiples of an industry standard rack mounting height dimension. For example, rackmount servers are generally referred to as “1U,” “2U,” “3U,” “4U,” etc. systems, where the “U” designation refers to one dimensional increment of 1.75 inches in height along the vertical members of an Electronics Industry Alliance (EIA) industry-standard computer racking/mounting structure. Thus, for example, a 2U rackmount server is generally designed to be approximately 3.5 inches in height less a small amount of clearance between vertically-adjacent rackmount servers in the rack (those skilled in the art will note that a standard rack is 19 inches wide; however, racks of other widths are available).

Mass production of rackmount servers may be especially difficult when different particular specifications (e.g., number of fan modules) are required for each manufactured rackmount server. Specifically, to mass produce rackmount servers, a plurality of, for example, 1U rackmount servers, may require exact manufacturing specifications, such that all of the 1U rackmount servers are identically manufactured. This may include, but is not limited to, identical numbers of electronic components, identical casing size, etc.

One of ordinary skill in the art will appreciate that a rackmount server includes one or more fan modules, each connected to a fan module connector. The blowing of air by the one or more fans removes heat generated by the electronic components from the rackmount server thereby maintaining an appropriate operating temperature for the electronic components. In order to allow air to pass through a rackmount server casing, one or more air vents are provided in the casing corresponding to the number of fan modules being employed.

### SUMMARY OF THE INVENTION

An airflow optimization apparatus for a server comprising a first member configured to attach to openings of an air vent on a server enclosure, wherein the attachment of the first member to the air vent prevents air leakage, and a second member configured to mount on top of a fan module connector within the server enclosure.

A method for installing an air flow optimization apparatus comprising, inserting a first member into openings of an air vent in a server enclosure, wherein the first member comprises attaching fins configured to be inserted into outer ends of the openings of the air vent, mounting a second member on top of a fan module connector, wherein the second member includes engaging portions configured to engage with the fan module connector.

### BRIEF DESCRIPTION OF DRAWINGS

FIG. 1 shows a top view of an air flow optimization apparatus in accordance with one or more embodiments of the present invention.

FIGS. 2A-2C show perspective views of a first member of an air flow optimization apparatus in accordance with one or more embodiments of the present invention.

FIG. 3 shows a perspective view of a first member of an air flow optimization apparatus in accordance with one or more embodiments of the present invention.

FIGS. 4A-4B show perspective views of a second member of an air flow optimization apparatus in accordance with one or more embodiments of the present invention.

FIG. 5 shows a perspective view of a second member of an air flow optimization apparatus in accordance with one or more embodiments of the present invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description. In general, embodiments of the invention relate to an air flow optimization apparatus.

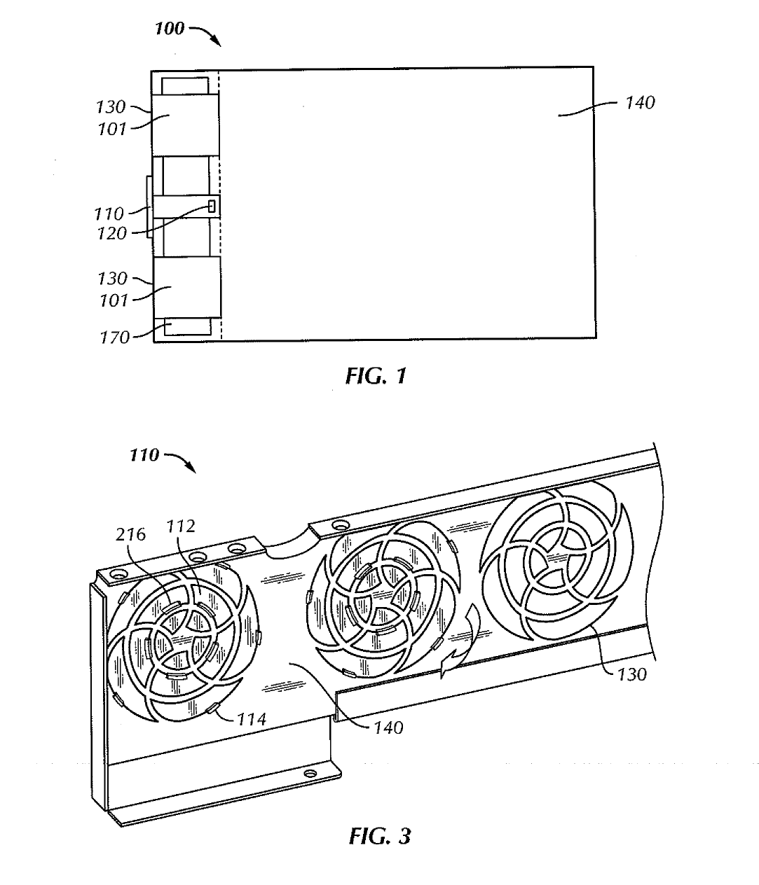

FIG. 1 shows a perspective view of an air flow optimization apparatus 100 in accordance with one or more embodiments of the present invention. The air flow optimization apparatus 100 includes a first member 110 and a second member 120. When the first member 110 and second member 120 are used together in conjunction with, for example, a rackmount server, optimized air flow may be achieved.

In order to provide mass production for rackmount servers, for example, one or more rackmount server casings may be manufactured with a standard number of air vents regardless of the number of fans required for a particular server. Because of this, the number of air vents may be greater than the number of installed fan modules in the rackmount server. For example, although a server casing is formed with four air vents at the time of manufacturing, a particular “2U” server may only require two or three fans for appropriate cooling. Furthermore, it may be the case that the rackmount server is expandable and thus, if expanded, the future installation of one or more additional fan modules would become necessary.

As shown in FIG. 1, the installation of one or more first members 110 in one or more air vents 130 of a rackmount server casing 140, and one or more second members 120 on top of one or more fan module connectors 171 in a fan module connector strip 170, may improve air flow. Specifically, one or more fan modules 101 directs air flow out of an adjacent, and corresponding air vent 130. The presence of an additional air vent 130 in the rackmount server casing 140 may disrupt air flow in the rackmount server.

Accordingly, the first member 110 may be configured to fill in a plurality of openings 131 in one or more air vents 130 in the rackmount server casing 140 to optimize air flow. In addition, the second member 120 may be configured to cover an exposed additional fan module connector 131, (i.e., without an installed fan module 101) to prevent dust from contaminating the fan module connector 131, and from preventing incorrect future placement of fan modules 101. One of ordinary skill in the art will appreciate that the first member 110 and the second member 120 may be formed from any material known in the art, such as plastics, more specifically, Nylon, polyethylene, high density polyethylene, polycarbonates, acrylics, and polypropylene, or the like. Further, one of ordinary skill in the art will also appreciate that the first member 110 and the second member 120 may be temporarily or permanently fixed to the rackmount server.

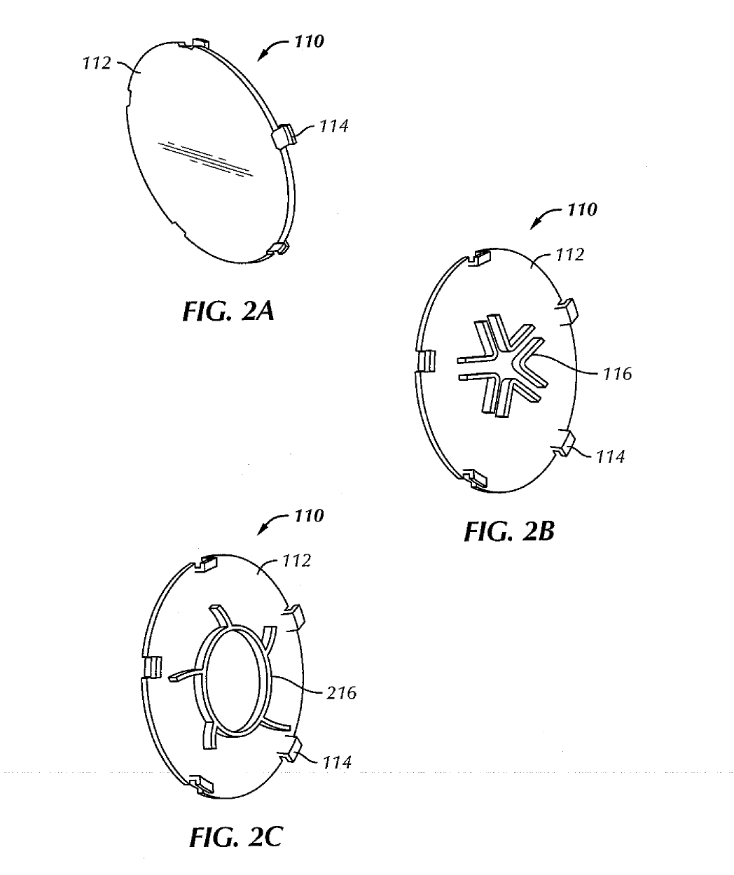

Referring now to FIGS. 2A-2C, perspective views of a first member 110 of an air flow optimization apparatus 100 are shown in accordance with one or more embodiments of the present invention. The first member 110 includes a circular body 112 and one or more attaching fins 114. One or more attaching fins 114 protrude perpendicularly and are equidistant from one another along the perimeter of the circular body 112. One of ordinary skill in the art will appreciate that although six attaching fins 114 are shown in FIGS. 2A-2C, any number of attaching fins 114 may be formed on the circular body 114, provided the number of attaching fins 114 allows the first member 110 to engage with a corresponding air vent (not shown). Further, one of ordinary skill in the art will also appreciate that although the body 112 shown in FIGS. 2A-2C has a circular cross-sectional shape, any shape known in the art may be used provided that the first member 110 is still able to engage with a corresponding air vent.

Further, to ensure that the first member 110 securely locks into the air vent, the first member 110 may include one or more engaging fins, 116 or 216, to fit into each opening of the air vent (not shown). One of ordinary skill in the art will appreciate that the shape and arrangement of the openings of the air vent may vary depending on the type of rackmount server, in particular, the type of rackmount server casing. Accordingly, for each first member 110, the number, size, and arrangement of engaging fins, 116 or 216, may vary.

Referring now to FIG. 2B, the first member 110 is shown having engaging fins 116 arranged to fit into, for example, the casing of a 1U server. Specifically, in one or more embodiments, the engaging fins 116 may be “V” shaped, such that each engaging fin 116 is placed adjacent one another in a circular formation. One of ordinary skill in the art will appreciate that although five engaging fins 116 are shown in FIG. 2B, any number of engaging fins 116 may be incorporated, depending on the type of rackmount server and corresponding air vents.

For example, a 2U rackmount server may have a different arrangement of openings in the air vents of the rackmount server casing. Accordingly, referring now to FIG. 2C, the first member 110 includes engaging fins 216 arranged to fit into the openings of an air vent in a 2U rackmount server. Specifically, the first member 110 includes engaging fins 216 which form a circle having a plurality of gaps, such that the gaps in the circle are replaced with engaging fins 216 disposed perpendicular to the circle of engaging fins 216. One of ordinary skill in the art will appreciate that although ten engaging fins 216 are shown in a distinct arrangement, any number of engaging fins 216 and any type of arrangement may be incorporated which corresponds to the configuration of openings in one or more air vents.

Further, one of ordinary skill in the art will appreciate that the attaching fins 114 and engaging fins 116 may be snapped on to the openings of one or more air vents to prevent air leakage. However, those of ordinary skill in the art will also appreciate that any means of attachment of the first device to one or more air vents known in the art may be used, such as, latching, hooking, etc. In addition, one of ordinary skill in the art will also appreciate that the circular body 112, the attaching fins 114, and the engaging fins 116 may be separately or integrally formed.

Turning to FIG. 3, a perspective view of the first member 110 described with respect to FIG. 2C is installed in a 2U rackmount server casing 240 is shown. Specifically, the attaching fins 114 are aligned with and inserted into the outer ends of openings 231 of air vents 230. Simultaneously, the engaging fins 216 are aligned with and inserted into the openings 231, such that they come into contact with the inner ends of the openings 231. As shown, the arrangement of the engaging fins 216 corresponds to the arrangement of the inner ends of the openings 231 of each air vent 230. In one or more embodiments, once the first member 110 is pushed into the openings 231 of the air vent 230, the first member 110 is turned clockwise a short distance to snap securely into place. One of ordinary skill in the art will appreciate that in one or more embodiments of the present invention, the first member 110 may not require turning clockwise to snap into place, but instead may instantly snap into place once inserted into the corresponding air vent 230.

Advantageously, covering the openings 231 of one or more air vents 230 with the first member 110 may optimize air flow by preventing leakage of air. Further, in the event that a fan module is installed adjacent to an air vent having a first member 110, the first member 110 can be easily removed to facilitate air flow.

In conjunction with the first member 110, as discussed previously, the air flow optimization apparatus 100 also includes the second member 120. Similar to the first member 110, the second member 120 may be configured to mount over a fan module connector of a fan module connector strip corresponding to a specific rackmount server, for example, a 1U or 2U server.

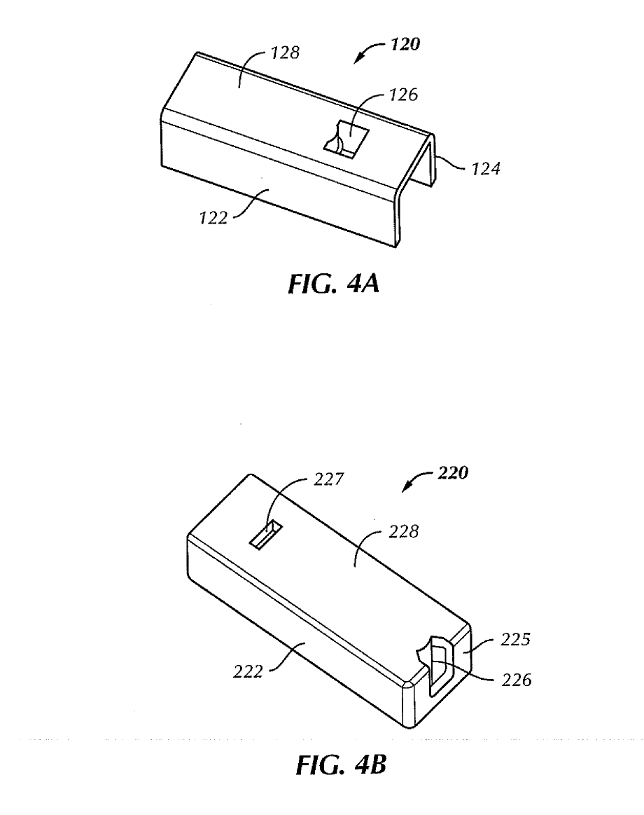

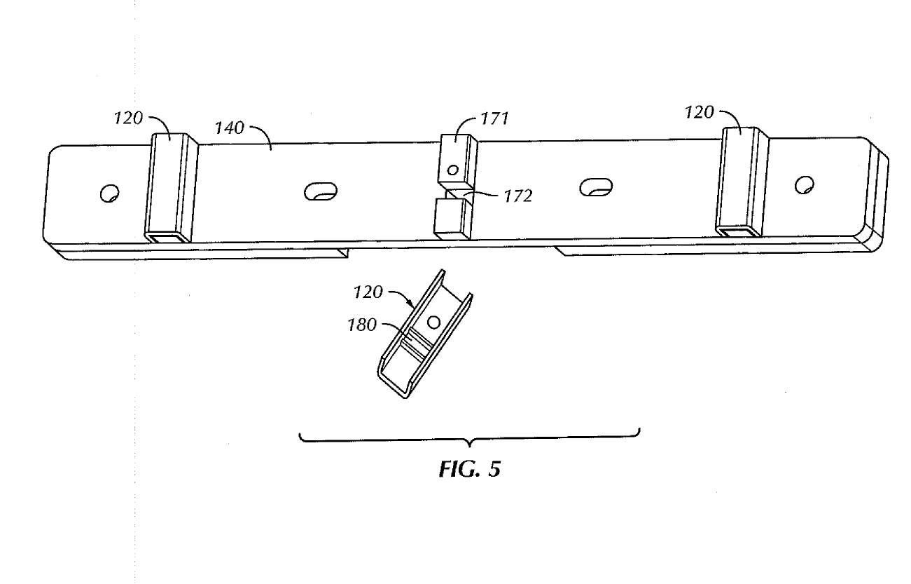

Referring now to FIG. 4A, a perspective view of a second member 120 in accordance with one or more embodiments of the present invention is shown. The second member 120 includes a rectangular base 128 and two perpendicular side walls, 122 and 124. The rectangular cross-section of the rectangular base 128 corresponds to the shape of a fan module connector, as described in FIG. 5. The side walls, 122 and 124, are disposed opposite one another along the longer edges of the rectangular base 128. In addition, the rectangular base 128 includes an aperture 126 to further secure the second member 120 to a corresponding fan module connector. Engaging portions (not shown) may also be included underneath the rectangular base 128 to engage the second member 120 with an associated fan module connector. Those of ordinary skill in the art will appreciate that although two side walls, 122 and 124, and one aperture 126, are shown in FIG. 4A, any number of side walls and apertures may be formed which correspond to the associated fan module connector.

For example, as shown in FIG. 4B, a perspective view of a second member 220 is shown in accordance with one or more embodiments of the present invention. The second member 220 may be used in conjunction with a 2U server casing and fan module connector. The second member 120 includes a rectangular base 228 and four side walls 222, 223, 224, 225. Specifically, side walls 222, 224 are disposed opposite one another along the long edges of rectangular base 228. In contrast, side walls 223, 225 are disposed opposite one another along short edges of rectangular base 228. The rectangular cross-section of the rectangular base 228 corresponds to the shape of a fan module connector, as described with respect to FIG. 5. In addition, the second member 220 includes an aperture 226 and a slit 227. The aperture 226 is formed between the rectangular base 228 and the side wall 225. The slit 227 is formed in the rectangular base 228 and disposed distal from the aperture 226. The incorporation of the aperture 226 and the slit 227 further secures the second member 220 to a corresponding fan module connector. Engaging portions (not shown) may also be included underneath the rectangular base 228 to engage the second member 220 with an associated fan module connector. One of ordinary skill in the art will appreciate that although certain configurations and numbers of side walls, apertures, and slits are shown in FIG. 4B, any number of side walls, apertures, and slits may be incorporated which correspond to an associated fan module connector.

One of ordinary skill in the art will appreciate that the second member, 120 and 220, as shown in FIGS. 4A-4B may act as a protective cover for corresponding fan module connectors, advantageously protecting an unused fan module connector from dust. Further, one of ordinary skill in the art will also appreciate that the second member may be formed in any shape known in the art, such that the second member may take the form of a “dummy” fan module for connection to an associated fan module connector. The presence of a “dummy” fan module may also advantageously serve as a protective cover for an associated fan module connector.

FIG. 5 is a perspective view of a fan module connector strip 170 having one or more fan module connectors 171 in accordance with one or more embodiments of the present invention. Mounted on one or more fan module connectors 171 is the second member 120 as described with respect to FIG. 4A. As shown, underneath the rectangular base 128 are engaging portions 180 for mounting the second member 120 onto the associated fan module connector 171. Specifically, the engaging portions 180 protrude perpendicularly from the bottom of the rectangular base 128, and also, extend horizontally along the width of the rectangular base 128. Accordingly, when the second member 120 is mounted onto the associated fan module connector 171, the engaging portions 180 align with and are inserted into a gap 172 in the fan module connector 171 for secure mounting. One of ordinary skill in the art will appreciate that in one or more embodiments of the present invention, the second member 120 may be mounted onto the fan module connector 171 by any means known in the art such as, sliding, snapping, etc.

One of ordinary skill in the art will also appreciate that, if it becomes necessary to install an additional fan module (not shown) into the covered fan module connector 171, the second member 120 may be easily removed by sliding or pulling the second member 120 away from the fan module connector 171.

One or more embodiments of the present invention may include one or more of the following advantages. The air flow optimization apparatus may be able to fool-proof the installation of fan modules on a mass production of servers. In particular, one or more embodiments of the present invention results in optimized air flow that can be tailored to each server platform, and allow implementation of a common enclosure. Implementation of a common enclosure may lead to lower costs and backwards compatibility to existing enclosure designs.

While the present invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An airflow optimization apparatus for a server comprising:
a first member configured to attach to openings of an air vent on a server enclosure, wherein the attachment of the first member to the air vent prevents air leakage; and
a second member configured to mount on top of a fan module connector within the server enclosure.

2. The air flow optimization apparatus according to claim 1, wherein the first member comprises, a body, and a plurality of attaching fins configured to attach the first member to outer ends of the openings of the air vent.

3. The air flow optimization apparatus according to claim 1, wherein the first member comprises a plurality of engaging fins configured to engage with inner ends of the openings of the air vent on the server enclosure.

4. The air flow optimization apparatus according to claim 2, wherein the body of the first member comprises a circular cross section.

5. The air flow optimization apparatus according to claim 3, wherein each of the plurality of engaging fins are “V” shaped and arranged in a circular formation.

6. The air flow optimization apparatus according to claim 3, wherein a portion of the plurality of engaging fins are arranged in a circular formation, and the remaining portion of the plurality of engaging fins are disposed perpendicular to the circular formation.

7. The air flow optimization apparatus according to claim 1, wherein the second member includes a rectangular base and two side walls.

8. The air flow optimization apparatus according to claim 1, wherein the second member includes a rectangular base and four side walls.

9. The air flow optimization apparatus according to claim 1, wherein the second member comprises at least one aperture.

10. The air flow optimization apparatus according to claim 1, wherein the second member comprises at least one engaging portion configured to engage with the fan module connector.

11. The air flow optimization apparatus according to claim 1, wherein the first member is comprised of a plastic material.

12. The air flow optimization apparatus according to claim 1, wherein the second member is comprised of a plastic material.

13. The air flow optimization apparatus according to claim 2, wherein the body and the attaching fins are integrally formed.

14. The air flow optimization apparatus according to claim 1, wherein the second member is a dummy fan module.

15. A method for installing an air flow optimization apparatus comprising:
inserting a first member into openings of an air vent in a server enclosure, wherein the first member comprises attaching fins configured to be inserted into outer ends of the openings of the air vent;
mounting a second member on top of a fan module connector, wherein the second member includes engaging portions configured to engage with the fan module connector.

16. The method according to claim 15, wherein the first member further comprises engaging fins configured to be inserted into inner ends of the openings of the air vent.

17. The method according to claim 15, further comprising turning the first member in a clockwise direction to snap the first member into a secure position in the openings of the air vent.
